(19) United States
(12) Patent Application Publication
(10) Pub. No.: US 2011/0212591 A1
(43) Pub. Date: Sep. 1, 2011

(54) METHOD FOR FABRICATING TRANSISTOR OF SEMICONDUCTOR DEVICE

(76) Inventors: Jae-Geun OH, Gyeonggi-do (KR); Young-Ho Lee, Gyeonggi-do (KR); Jin-Ku Lee, Gyeonggi-do (KR); Mi-Ri Lee, Gyeonggi-do (KR)

(21) Appl. No.: 12/964,562

(22) Filed: Dec. 9, 2010

(30) Foreign Application Priority Data
Feb. 26, 2010 (KR) 10-2010-0018176

(51) Int. Cl. H01L 21/336; H01L 21/265

(52) U.S. Cl. 438/303; 438/530; 257/E21.409; 257/E21.334

(57) ABSTRACT

A method for fabricating a transistor of a semiconductor device includes: forming a gate pattern over a substrate; forming a junction region by performing an on implantation process onto the substrate at opposite sides of the gate pattern; performing a solid phase epitaxial (SPE) process on the junction region at a temperature approximately ranging from 770° C. to 850° C.; and performing a rapid thermal annealing (RTA) process on the junction region.

### CROSS-REFERENCE TO RELATED APPLICATIONS

The present application claims priority of Korean Patent Application No. 10-2010-0018176, filed on Feb. 26, 2010, which is incorporated herein by reference in its entirety.

### BACKGROUND OF THE INVENTION

Exemplary embodiments of the present invention relate to a semiconductor device fabrication method, and more particularly, to a method for fabricating a transistor of a semiconductor device.

As the size of semiconductor devices shrinks, shallow source/drain junction depth is desired in order to secure short channel is margins. While the formation of a shallow junction is desired to be performed at a low temperature with a low thermal budget, in order to decrease the resistance of a junction, technology for performing a thermal treatment at a high temperature for a short period of time such as Rapid Thermal Annealing (RTA) equipment is used. Since RTA equipment is capable of performing a spike thermal treatment, it is often used to perform a thermal treatment at a high temperature for a short period of time.

However, even if the thermal treatment is performed with the RTA equipment such as an equipment using a flash or laser, thermal treatment does not produce adequate results. This is because RTA method have characteristics where using flash or laser does not reduce soak time and processing time. This is further attributed to a short processing time of the RTA method, where the recovery of a layer from damage caused by on implantation and activation of a dopant occur simultaneously and the two processes are not adequately performed.

Therefore, a technology to improve device characteristics by adequately performing both of the recovery of a layer from a damage by on implantation and the activation of a dopant is useful.

### SUMMARY OF THE INVENTION

An embodiment of the present invention is directed to a method for fabricating a transistor for a semiconductor device that adequately performs both of the recovery of a layer from a damage by on implantation and the activation of a dopant.

In accordance with an embodiment of the present invention, a method for fabricating a transistor of a semiconductor device includes: forming a gate pattern over a substrate; forming a junction region by performing an on implantation process onto the substrate at opposite sides of the gate pattern; performing a solid phase epitaxial (SPE) process onto the junction region at a temperature approximately ranging from 770° C. to 850° C.; and performing a rapid thermal annealing (RTA) process on the junction region.

In accordance with another embodiment of the present invention, a method for fabricating a semiconductor device includes: forming a junction region by performing an on implantation process onto a substrate; performing a solid phase epitaxial (SPE) process on the junction region at a temperature approximately ranging from 770° C. to 850° C.; and performing a rapid thermal annealing (RTA) process on the junction region.

In accordance with further another embodiment of the present invention, a method for fabricating a semiconductor device includes: forming a junction region by performing an ion implantation process onto a substrate; performing a solid phase epitaxial (SPE) process onto the substrate to regrow a portion of the substrate damaged from the on implantation; and performing a rapid thermal annealing (RTA) process on the substrate to activate dopants in the junction region, is wherein the SPE process is performed at a temperature lower than that of the RTA process.

### BRIEF DESCRIPTION OF THE DRAWINGS

FIGS. 1A to 1D are cross-sectional views illustrating a method for fabricating a transistor of a semiconductor device in accordance with an embodiment of the present invention.

FIGS. 2A and 2C are cross-sectional views illustrating a method for fabricating a semiconductor device in accordance with an embodiment of the present invention.

FIGS. 3A and 3B are Transmission Electron Microscopic (TEM) pictures describing a change of a substrate in accordance with an embodiment of the present invention.

FIG. 4 is a graph comparing the concentration of a dopant between a thin film according to an embodiment of the present invention and a thin film according to a conventional technology.

FIGS. 5A and 5B are graphs comparing the characteristics of an NMOS device in accordance with an embodiment of the present invention.

FIGS. 6A and 6B are graphs comparing the characteristics of a PMOS device in accordance with an embodiment of the present invention.

FIG. 7 is a graph comparing DIBL characteristics and Idsat according to an embodiment of the present invention.

### DESCRIPTION OF SPECIFIC EMBODIMENTS

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

### 1^{ST} Embodiment

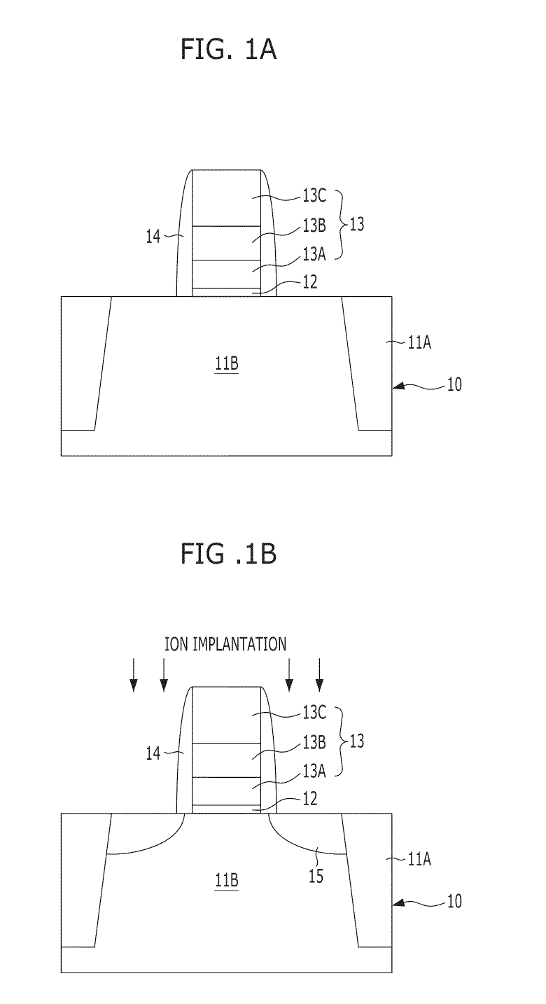

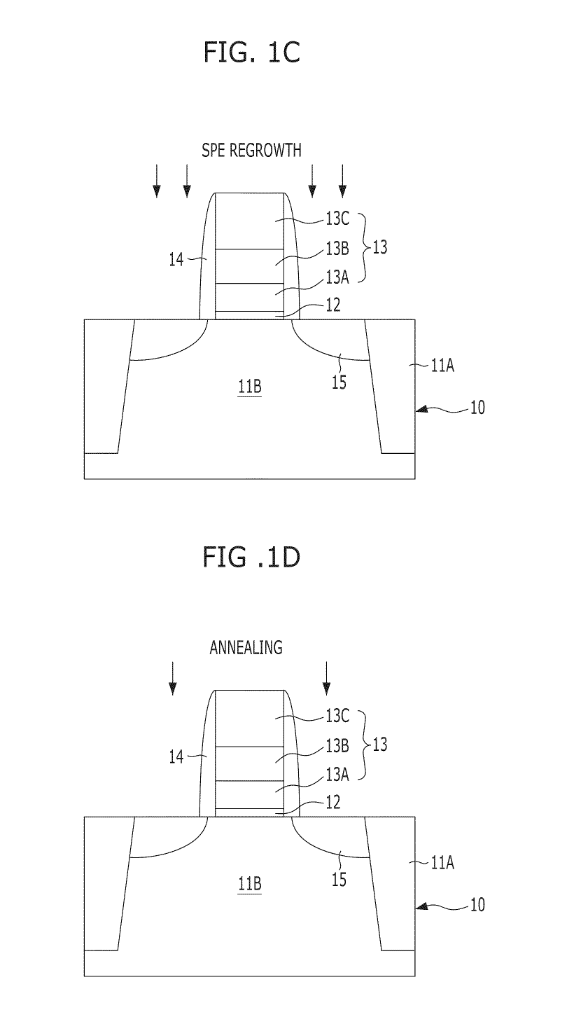

FIGS. 1A to 1D are cross-sectional views illustrating a method for fabricating a transistor of a semiconductor device in accordance with an embodiment of the present invention.

Referring to FIG. 1A, an isolation layer 11A is formed over a substrate 10 through a Shallow Trench Isolation (STI) process. Herein, the isolation layer 11A may be an oxide layer such as a high-density plasma oxide (HDP) layer or a spin-on dielectric (SOD) layer. The isolation layer 11A defines active regions 11B in-between.

Subsequently, a gate pattern 13 is formed over the substrate 10. A gate insulation layer 12 is formed between the substrate 10 and the gate pattern 13. The gate insulation layer 12 insulates the substrate 10 and the gate pattern 13 from each other and it is formed of an insulating material such as an oxide layer.

The gate pattern 13 is formed as a stacked structure where a first electrode 13A, a second electrode 13B, and a gate hard mask 13C are stacked. Herein, the first electrode 13A is formed of polysilicon and the second electrode 13B is formed of a metallic electrode. For example, the second electrode 13B is formed of tungsten, and a barrier metal layer may be formed before the formation of the tungsten second electrode 13B in order to prevent diffusion. The gate hard mask 13C is used as an etch mask when the gate pattern 13 is formed, and the gate hard mask 13C prevents the second electrode 13B from being exposed during a subsequent process for forming a plug. In particular, although the gate pattern 13 is formed as a planar type according to an example, the gate pattern 13 may also be formed as any one type selected from the group consisting of a polygonal recess pattern, a pin pattern, and a saddle pin pattern.

Subsequently, gate spacers 14 are formed on the sidewalls of the gate pattern 13. The gate spacers 14 are used to protect the sidewalls of the gate pattern 13, and they are formed of an insulating material such as a nitride layer.

Referring to FIG. 1B, source/drain regions 15 are formed by performing an ion implantation on the substrate 10 at both sides of the gate pattern 13. When the substrate 10 is a P-type substrate, a P-type dopant may be used for the ion implantation. When the substrate 10 is an N-type substrate, an N-type dopant may be used for the ion implantation. The P-type dopants include boron (B) and the N-type dopants include phosphorous (P) and arsenic (As).

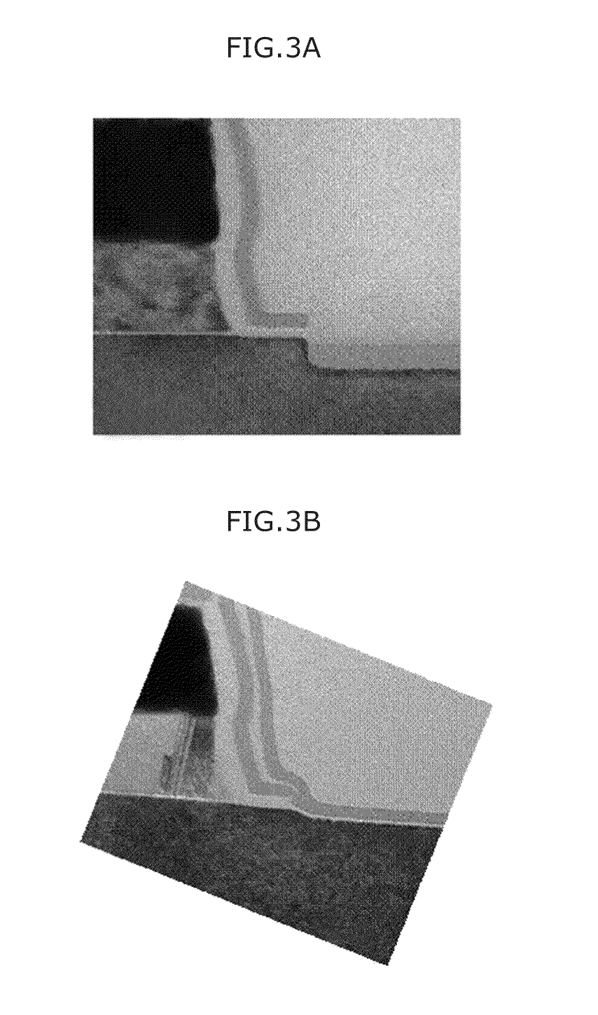

Subsequent to the on implantation on the substrate 10, the portion of the substrate 10 damaged from the on implantation is changed into an amorphous layer. Detailed explanation of the change is provided later in reference to FIG. 3A.

Referring to FIG. 1C, a Solid Phase Epitaxial (SPE) process is performed to regrow the portion of the substrate 10 damaged from the on implantation.

Therefore, the portion of the substrate 10 damaged from the on implantation is regrown and becomes a monocrystalline layer which is the same as the substrate 10.

Herein, the SPE process may be performed at a temperature approximately ranging from 770° C. to 850° C. for a period of time approximately ranging from one to 120 seconds. Also, the SPE process may be performed in-situ in the same chamber as the chamber where a subsequent annealing process is to be performed, or it may be performed in another chamber ex-situ.

Since the SPE process is performed at a relatively low temperature for a short time, compared with the annealing process, the dopant ion-implanted into the junction region 15 in FIG. 1B is hardly diffused,

Referring to FIG. 1D, a Rapid Thermal Annealing (RTA) process is performed to diffuse the dopant which is ion-implanted into the junction region 15.

The RTA process may be performed in an msec RTA equipment. For example, the RTA process may be performed using any one equipment selected from the group consisting of xenon (Xe) lamp flash equipment, arc ramp flash equipment, and a laser annealing equipment. Here, the RTA process may be performed for approximately 1 msec to approximately 100 msec.

After the on implantation, the damaged layer 15 is recovered through the SPE process and the dopant is activated through the RTA process. As a result, the concentration of the dopant in the thin film is increased and thus resistance is decreased. Also, since the scattering amount of hole/electrons is decreased as well, device current is increased and the punch characteristics (NB IW) of a device are improved, too.

### 2^{ND} Embodiment

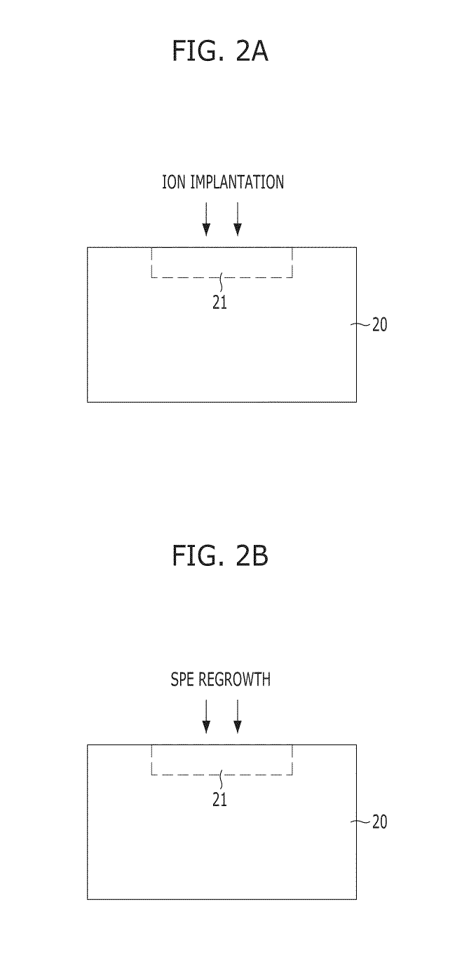

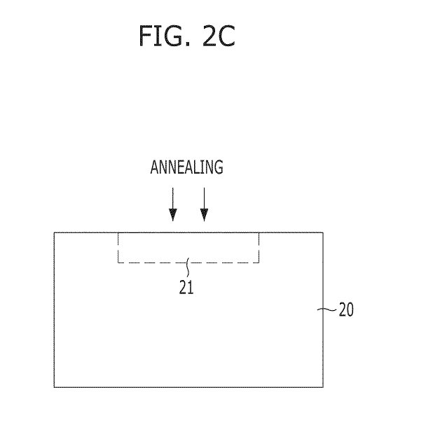

FIGS. 2A to 2C are cross-sectional views illustrating a method for fabricating a transistor of a semiconductor device in accordance with an embodiment of the present invention.

Referring to FIG. 2A, a junction region 21 is formed by performing an on implantation on the substrate 20. When the substrate 20 is a P-type substrate, a P-type dopant may be used for the on implantation. When the substrate 20 is an N-type substrate, an N-type dopant may be used for the on implantation. The P-type dopant may be boron (3) and the N-type dopant may be phosphorous (P) or arsenic (As).

The portion of the substrate 20 damaged from the on implantation is changed into an amorphous layer. The detailed description of the change will be provided later in reference to FIG. 3A.

Referring to FIG. 2B, a Solid Phase Epitaxial (SPE) process is performed to regrow the portion of the substrate 20 damaged from the on implantation.

Therefore, the portion of the substrate 20 damaged from the on implantation is regrown and becomes a monocrystalline layer which is the same as the material for the substrate 20.

Herein, the SPE process may be performed at a temperature ranging from approximately 770° C. to approximately 850° C. for a period of time approximately ranging from 1 second to 120 seconds. Also, the SPE process may be performed in-situ in the same chamber as the chamber where a subsequent annealing process is to be performed, or it may be performed in another chamber ex-situ.

Since the SPE process is performed at a relatively low temperature for a short time, compared with the annealing process, the dopant ion-implanted into the junction region 21 in FIG. 2B is hardly diffused.

Referring to FIG. 2C, a Rapid Thermal Annealing (RTA) process is performed to diffuse the dopant which is ion-implanted into the junction region 21.

The RTA process may be performed in an msec RTA equipment. For example, the RTA process may be performed using any one equipment selected from the group consisting of xenon (Xe) lamp flash equipment, arc ramp flash equipment, and a laser annealing equipment. Here, the RTA process may be performed for a period of time approximately ranging from 1 msec to 100 msec.

After the on implantation, the damaged layer is recovered through the SPE process and the dopant is activated through the RTA process. As a result, the concentration of the dopant in the thin film is increased and thus resistance is decreased. Also, since the scattering amount of hole/electrons is decreased as well, device current is increased and appropriate punch characteristics (DIBL) of a device may be obtained.

FIGS. 3A and 3B are Transmission Electron Microscopic (TEM) pictures describing a change of a substrate in accordance with an embodiment of the present invention.

Referring to FIG. 3A, after the on implantation process is performed onto the source/drain region, it may be seen that the surface of the substrate is damaged and the structure of the components are changed into an amorphous structure so as to form an amorphous layer.

In the amorphous layer, the concentration of the dopant within the thin film is relatively low and resistance is increased. Here, in performing the RTA process without performing a SPE regrowth process, the annealing time is relatively short so that the damaged layer is not sufficiently recovered.

Therefore, referring to FIG. 3B, in an embodiment of the present invention, the amorphous layer is arranged into the monocrystalline structure by performing the SPE process and thereby regrowing the damaged layer.

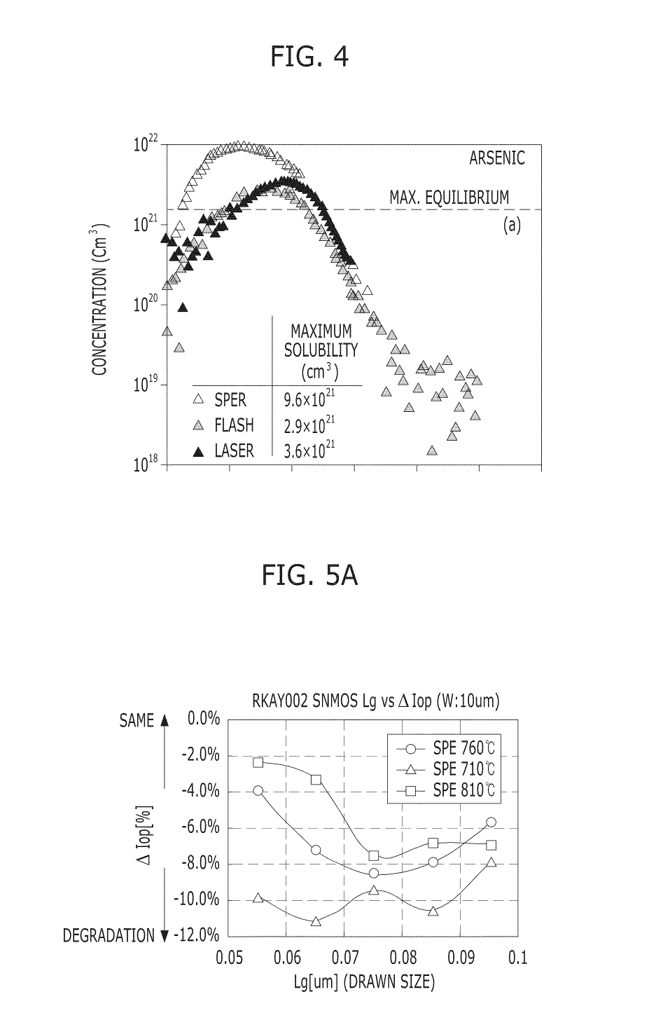

FIG. 4 is a graph comparing the concentration of a dopant between a thin film according to an embodiment of the present invention and a thin film according to conventional technology.

FIG. 4 shows a comparison of the concentration of the dopant within the thin film formed according to the embodiment of the present invention through the SPE regrowth process and the RTA process, the concentration of a dopant within a thin film formed through a flash thermal treatment, and the concentration of a dopant within a thin film formed through a laser thermal treatment. The graph shows that the concentration of the dopant of the thin film formed through the SPE regrowth process is higher than those of the thin films formed through the flash thermal treatment and the laser thermal treatment.

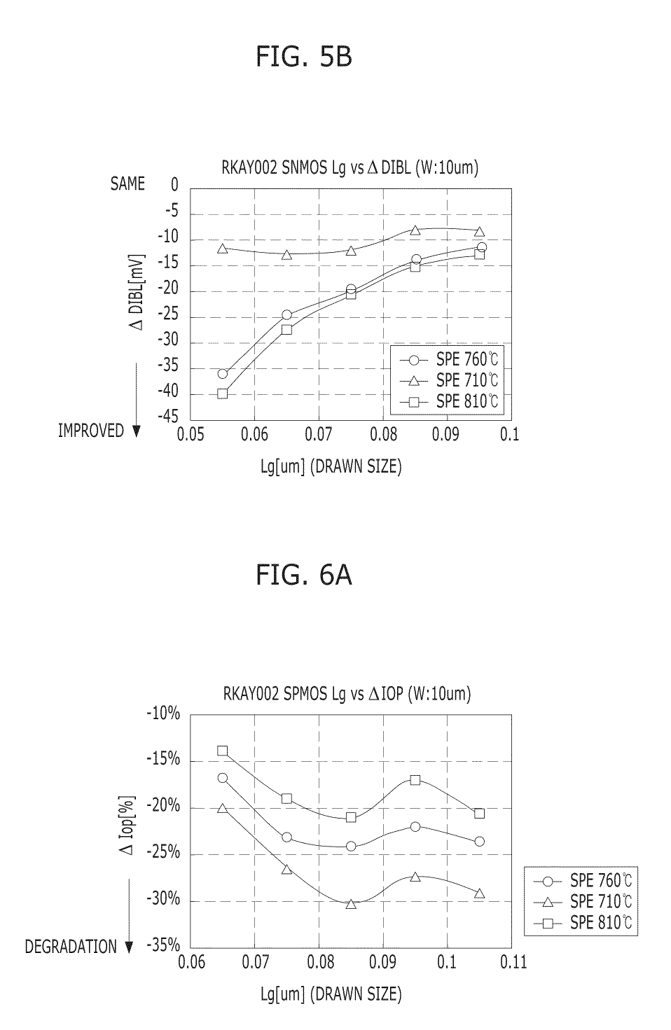

FIGS. 5A and 5B are graphs comparing the characteristics of an NMOS device in accordance with an embodiment of the present invention. FIG. 5A shows current characteristics, and FIG. 5B shows DIBL characteristics.

Referring to FIG. 5A, current characteristics according to temperature during the SPE process are compared. The graph shows that as the temperature of the SPE process increases from approximately 710° C. to approximately 760° C. and then to approximately 810° C., deterioration of the current characteristics becomes slow.

Referring to FIG. 5B, the DIBL characteristics according to temperature during the SPE process are compared, The graph shows that as the temperature of the SPE process increases from approximately 710° C. to approximately 760° C. and then to approximately 810° C., the DIBL characteristics are improved, and particularly, when the SPE process is performed at approximately 810° C., the DIBL characteristics may be improved by approximately 40 mV.

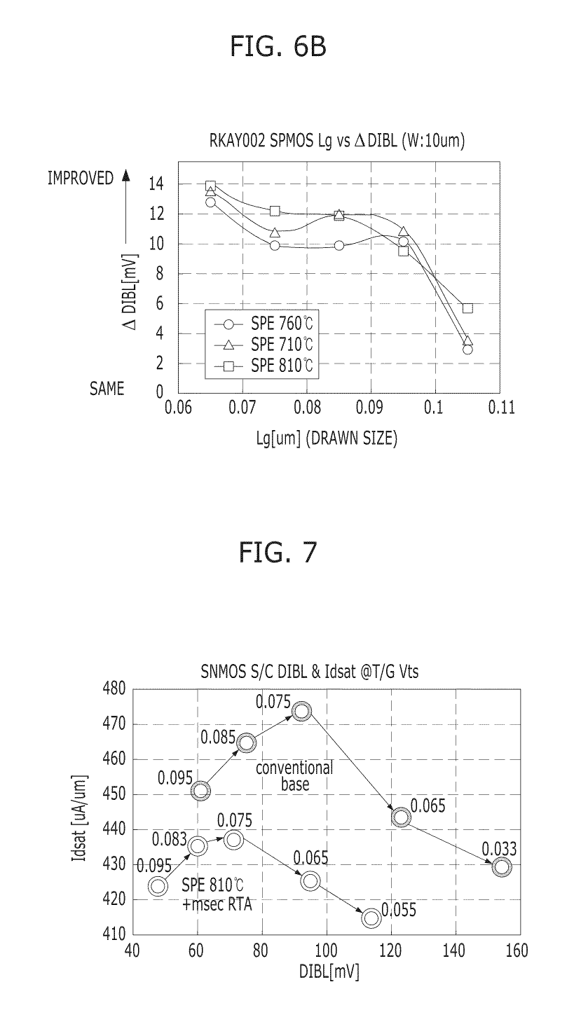

FIGS. 6A and 6B are graphs comparing the characteristics of a PMOS device in accordance with an embodiment of the present invention. FIG. 6A shows current characteristics, and FIG. 6B shows DIBL characteristics.

Referring to FIG. 6A, the current characteristics according to temperature during the SPE process are compared. Herein, the graph shows that as the temperature of the SPE process increases from approximately 710° C. to approximately 760° C. and then to approximately 810° C., deterioration of the current characteristics becomes slow.

Referring to FIG. 6B, the DIBL characteristics according to temperature during the SPE process are compared. The graph shows that as the temperature of the SPE process increases from approximately 710° C. to approximately 760° C. and then to approximately 810° C., the DIBL characteristics are improved, and particularly, when the SPE process is performed at approximately 810° C., the DIBL characteristics may be improved by approximately 14 mV.

FIG. 7 is a graph comparing DIBL characteristics and Idsat according to an embodiment of the present invention.

Referring to FIG. 7, a conventional method and a method of performing the SPE process at approximately 810° C. according to an example are compared.

Herein, the conventional method suffers much DIBL degradation, while a method of performing the SPE process at approximately 810° C. according to an example experiences reduced degradation in the DIBL characteristics as the degree of the current reduction becomes less.

A method for fabricating a transistor of a semiconductor device according to an exemplary embodiment of the invention as described above may increase the concentration of a dopant in a thin film and thereby decrease resistance by performing an on implantation process, recovering a damaged thin film through an SPE process, and activating a dopant through a rapid thermal annealing process.

Since the scattering of holes/electrons is decreased according to an exemplary embodiment of the invention, device current rises and proper punch characteristics (DIBL) may be obtained.

While the present invention has been described with respect to the specific embodiments, it will be apparent to those skilled in the art that various changes and modifications may be made without departing from the spirit and scope of the invention as defined in the following claims.

What is claimed is:

1. A method for fabricating a transistor of a semiconductor device, comprising:
forming a gate pattern over a substrate;
forming a junction region by performing an on implantation process on the substrate at opposite sides of the gate pattern;
performing a solid phase epitaxial (SPE) process on the junction region at a temperature approximately ranging from 770° C. to 850° C.; and
performing a rapid thermal annealing (RTA) process on the junction region.

2. The method of claim 1, wherein in the forming of the junction region,
when the substrate is an N-type substrate, the on implantation is performed using an N-type dopant.

3. The method of claim 1, wherein in the forming of the junction region,
when the substrate is a P-type substrate, the on implantation is performed using a P-type dopant.

4. The method of claim 1, wherein the SPE process is performed for a period of time approximately ranging from 1 second to 120 seconds.

5. The method of claim 1, wherein the RTA process is performed in an msec RTA equipment.

6. The method of claim 1, wherein the RTA process is performed in any one equipment selected from the group consisting of a xenon (Xe) lamp flash equipment, an arc ramp flash equipment, and a laser annealing equipment.

7. The method of claim 1, wherein the RTA process is performed for a period of time approximately ranging from 1 msec to 100 msec.

8. The method of claim 1, wherein the forming of the junction region by performing the on implantation process includes doping the junction regions with a dopant and the performance of the rapid thermal annealing (RTA) process on the junction region includes performing an annealing process to diffuse the dopant in the junction region.

9. A method for fabricating a semiconductor device, comprising:
forming a junction region by performing an on implantation process on a substrate;
performing a solid phase epitaxial (SPE) process on the junction region at a temperature approximately ranging from 770° C. to 850° C.; and
performing a rapid thermal annealing (RTA) process on the junction region.

10. The method of claim 9, wherein the SPE process is performed for a period of time approximately ranging from 1 second to 120 seconds.

11. The method of claim 9, wherein the RTA process is performed for approximately 1 msec to approximately 100 msec.

12. The method of claim 9, wherein the RTA process is performed in an msec RTA equipment.

13. The method of claim 9, wherein the RTA process is performed in any one equipment selected from the group consisting of a xenon (Xe) lamp flash equipment, an arc ramp flash equipment, and a laser annealing equipment.

14. A method for fabricating a semiconductor device, comprising:
forming a junction region by performing an on implantation process onto a substrate;
performing a solid phase epitaxial (SPE) process on the substrate to regrow a portion of the substrate damaged from the on implantation; and
performing a rapid thermal annealing (RTA) process on the substrate to activate dopants in the junction region,
wherein the SPE process is performed at a temperature lower than that of the RTA process.

15. The method of claim 14, wherein the SPE process is performed at a temperature ranging from approximately 770° C. to approximately 850° C.

16. The method of claim 14, wherein, during the SPE process is performed onto the substrate, the portion of the substrate damaged from the on implantation is regrown and becomes a monocrystalline layer which is the same material as the substrate.

17. The method of claim 14, wherein the SPE process is performed for a period approximately ranging from 1 second to 120 seconds.

18. The method of claim 14, wherein the RTA process is performed for a period approximately ranging from 1 msec to 100 msec.

19. The method of claim 14, wherein the RTA process is performed in any one equipment selected from the group consisting of a xenon (Xe) lamp flash equipment, an arc ramp flash equipment, and a laser annealing equipment.
